(19) United States
(12) Patent Application Publication
(10) Pub. No.: US 2023/0328938 A1
(43) Pub. Date: Oct. 12, 2023

(54) POWER MODULE

(71) Applicant: DENSO CORPORATION, Kariya-city (JP)

(72) Inventors: Tetsuya MATSUOKA, Kariya-city (JP); Yuta HASHIMOTO, Kariya-city (JP); Kazuya TAKEUCHI, Kariya-city (JP); Tomoki KOZAWA, Kariya-city (JP)

(73) Assignee: DENSO CORPORATION, Kariya-city (JP)

(21) Appl. No.: 18/334,429

(22) Filed: Jun. 14, 2023

Related U.S. Application Data
(63) Continuation of application No. PCT/JP2021/043362, filed on Nov. 26, 2021.

(30) Foreign Application Priority Data
Jan. 7, 2021 (JP) 2021-001692

(51) Int. Cl. H05K 7/20

(52) U.S. Cl. CPC H05K 7/20936; H05K 7/20327

(57) ABSTRACT

A power module has a semiconductor module and a cooling device. The cooling device has a cooling unit provided in the semiconductor module so as to be capable of conducting heat, a supply pipe configured to supply refrigerant to an interior of the cooling unit, and a discharge pipe configured to discharge the refrigerant that is flowed inside the cooling unit. The semiconductor module and the cooling unit are arranged in a z-direction. The supply pipe and the discharge pipe are spaced apart in a x-direction. Each of the supply pipe and the discharge pipe faces the semiconductor module in a y-direction.

### CROSS REFERENCE TO RELATED APPLICATIONS

The present application is a continuation application of International Patent Application No. PCT/JP2021/043362 filed on Nov. 26, 2021, which designated the U.S. and claims the benefit of priority from Japanese Patent Application No. 2021-001692 filed in Japan filed on Jan. 7, 2021, the entire disclosure of the above application is incorporated herein by reference.

### TECHNICAL FIELD

The present disclosure relates to a power module.

### BACKGROUND

An electric vehicle is known that includes an inverter, a housing, and a heat sink. The inverter is connected with a motor via a three-phase line.

### SUMMARY

A power module in which an increase in size is suppressed is provided.

A power module according to one aspect of the present disclosure includes a semiconductor module having a semiconductor element, a terminal connected to the semiconductor element, and a resin portion covering each of the semiconductor element and the terminal, and a cooling device having a cooling unit provided in the semiconductor module so as to be capable of conducting heat, a supply pipe configured to supply refrigerant to an interior of the cooling unit, and a discharge pipe configured to discharge the refrigerant that is flowed inside the cooling unit. The supply pipe and the discharge pipe are spaced apart in a lateral direction orthogonal to an alignment direction in which the semiconductor module and the cooling unit are aligned, and the supply pipe and the discharge pipe face the semiconductor module in a vertical direction orthogonal to the lateral direction and the alignment direction.

### BRIEF DESCRIPTION OF DRAWINGS

FIG. 1 is a circuit diagram illustrating an in-vehicle system;

FIG. 2 is a diagram illustrating a top view of a power card;

FIG. 3 is a diagram illustrating an end view of the power card;

FIG. 4 is a diagram illustrating a perspective view of a power module;

FIG. 5 is a diagram illustrating a top view of the power module;

FIG. 6 is a diagram illustrating a side view of the power module;

FIG. 7 is a diagram illustrating an end view of the power module;

FIG. 8 is a diagram illustrating a perspective view showing a modified example of the power module;

FIG. 9 is a diagram illustrating a top view showing a modified example of the power module;

FIG. 10 is a diagram illustrating a top view showing a modified example of the power module;

FIG. 11 is a diagram illustrating a top view showing a modified example of the power module;

FIG. 12 is a diagram illustrating a top view showing a modified example of the power module; and

FIG. 13 is a diagram illustrating a top view showing a modified example of the power module.

### DETAILED DESCRIPTION

In an assumable example, an electric vehicle is known that includes an inverter, a housing, and a heat sink. The inverter is connected with a motor via a three-phase line.

The housing has a pair of leg portions and a connecting portion that connects them. The connecting portion is positioned between the pair of leg portions. A coolant flows through each of the pair of leg portions and the connecting portion.

A heat sink is provided between the pair of leg portions. The heat sink is arranged the connecting portion side by side. The inverter is provided between an upper surface of the heat sink and the connecting portion.

In the electric vehicle, the three-phase line is provided between the side surface of the heat sink and the leg portions. Therefore, there is a possibility that a size in a direction in which the pair of leg portions are arranged side by side may increase.

A power module in which an increase in size is suppressed is provided.

A power module according to one aspect of the present disclosure includes a semiconductor module having a semiconductor element, a terminal connected to the semiconductor element, and a resin portion covering each of the semiconductor element and the terminal, and a cooling device having a cooling unit provided in the semiconductor module so as to be capable of conducting heat, a supply pipe configured to supply refrigerant to an interior of the cooling unit, and a discharge pipe configured to discharge the refrigerant that is flowed inside the cooling unit. The supply pipe and the discharge pipe are spaced apart in a lateral direction orthogonal to an alignment direction in which the semiconductor module and the cooling unit are aligned, and the supply pipe and the discharge pipe face the semiconductor module in a vertical direction orthogonal to the lateral direction and the alignment direction.

This configuration suppresses an increase in the size of the power module in a lateral direction.

The following describe embodiments for carrying out the present disclosure with reference to the drawings. In each embodiment, parts corresponding to the elements described in the preceding embodiments are denoted by the same reference numerals, and redundant explanation may be omitted. When only a part of the configuration is described in each embodiment, another embodiment described previously may be applied to the other parts of the configuration.

When, in each embodiment, it is specifically described that combination of parts is possible, the parts can be combined. In a case where any obstacle does not especially occur in combining the parts of the respective embodiments, it is possible to partially combine the embodiments, the embodiment and the modification, or the modifications even when it is not explicitly described that combination is possible.

### First Embodiment

### <In-Vehicle System>

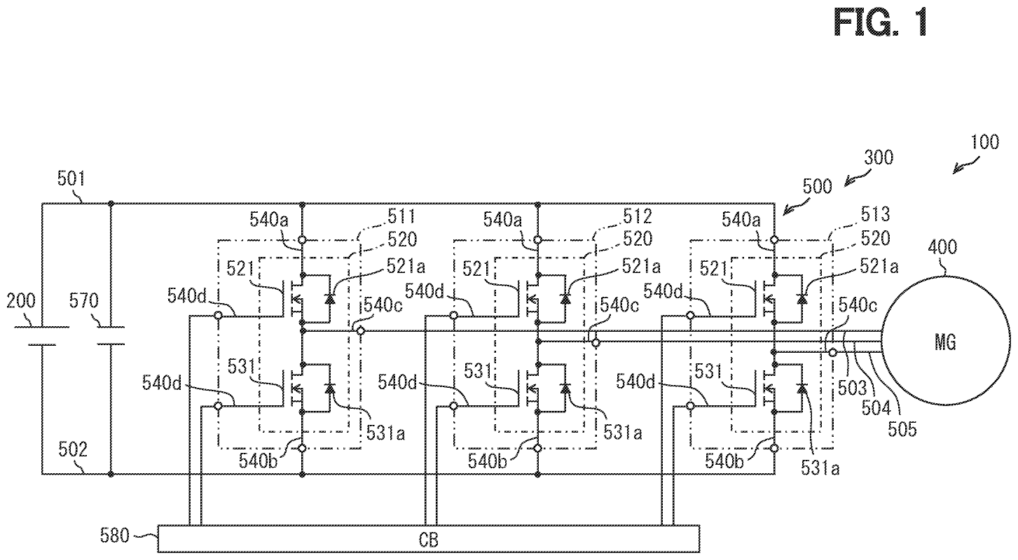

First, an in-vehicle system 100 will be described based on FIG. 1. The in-vehicle system 100 is a system for an electric vehicle. The in-vehicle system 100 has a battery 200, a power conversion unit 300, and a motor 400.

Further, the in-vehicle system 100 has a plurality of ECUs (not shown). The ECUs transmit signals to and receive signals from each other via a bus wiring. The ECUs control the electric vehicle in a cooperative manner. The ECUs control the regeneration and power running of the motor 400 according to a SOC of the battery 200. SOC is an abbreviation for State Of Charge. ECU is an abbreviation of Electronic Control Unit.

The battery 200 includes a plurality of secondary batteries. The secondary batteries form a battery stack connected in series. The SOC of the battery stack corresponds to the SOC of the battery 200. As the secondary batteries, a lithium ion secondary battery, a nickel hydrogen secondary battery, an organic radical battery, or the like may be employed.

A power conversion device 500 included in the power conversion unit 300 performs power conversion between the battery 200 and the motor 400. The power conversion device 500 converts the DC power of the battery 200 into AC power. The power conversion device 500 converts AC power generated by power generation (i.e., regeneration) of the motor 400 into DC power.

The motor 400 is connected to a shaft of an electric vehicle which is not shown. The rotational energy of the motor 400 is transmitted to traveling wheels of the electric vehicle via the shaft. On the contrary, the rotational energy of the traveling wheels is transmitted to the motor 400 via the shaft. In the drawings, the motor 400 is denoted as MG.

The motor 400 is electrically driven by an AC power supplied from the power conversion device 500. This applies a propulsive force to the running wheels. Further, the motor 400 is regenerated by the rotational energy transmitted from the traveling wheels. The AC power generated by this regeneration is converted into DC power by the power conversion device 500. This DC power is supplied to the battery 200. The DC power is also supplied to various electric loads mounted on the electric vehicle.

### <Power Conversion Device>

Next, the power conversion device 500 will be described. The power conversion device 500 includes an inverter. The inverter converts the DC power of the battery 200 into AC power. This AC power is supplied to the motor 400. Further, the inverter converts the AC power generated by the motor 400 into DC power. This DC power is supplied to the battery 200 and various electric loads.

As shown in FIG. 1, the power conversion device 500 includes a P bus bar 501 and a N bus bar 502. The battery 200 is connected to these P bus bar 501 and N bus bar 502. The P bus bar 501 is connected to a positive electrode of the battery 200. The N bus bar 502 is connected to a negative electrode of the battery 200.

Further, the power conversion device 500 includes a U-phase bus bar 503, a V-phase bus bar 504, and a W-phase bus bar 505. The motor 400 is connected to the U-phase bus bar 503, the V-phase bus bar 504, and the W-phase bus bar 505. In FIG. 1, connection parts of the various bus bars are indicated by white circles. These connection parts are electrically connected by, for example, bolts or welding.

The power conversion device 500 has a smoothing capacitor 570 and a U-phase semiconductor module 511 to a W-phase semiconductor module 513. The smoothing capacitor 570 has two electrodes. The P bus bar 501 is connected to one of these two electrodes. The N bus bar 502 is connected to the other of the two electrodes.

Each of the U-phase semiconductor module 511 to the W-phase semiconductor module 513 has a high-side switch 521 and a low-side switch 531. Each of the U-phase semiconductor module 511 to the W-phase semiconductor module 513 has a high-side diode 521a and a low-side diode 531a. The high side switch 521 and the low side switch 531 correspond to active elements.

In the present embodiment, an n-channel type MOSFET is employed as each of the high-side switch 521 and the low-side switch 531. As shown in FIG. 1, the source electrode of the high side switch 521 and the drain electrode of the low side switch 531 are connected. In this configuration, the high-side switch 521 and the low-side switch 531 are connected in series.

Further, a cathode electrode of the high-side diode 521a is connected to a drain electrode of the high-side switch 521. An anode electrode of the high-side diode 521a is connected to a source electrode of the high-side switch 521. In this configuration, the high-side diode 521a is connected in anti-parallel to the high-side switch 521.

Similarly, a cathode electrode of the low-side diode 531a is connected to a drain electrode of the low-side switch 531. An anode electrode of the low-side diode 531a is connected to a source electrode of the low-side switch 531. In this configuration, the low-side diode 531a is connected in anti-parallel to the low-side switch 531.

The high-side switch 521 and the high-side diode 521a described above are formed on a first semiconductor chip. The low-side switch 531 and the low-side diode 531a are formed on a second semiconductor chip.

The high-side diode 521a may be a body diode of the high-side switch 521, or may be another diode. The low-side diode 531a may be a body diode of the low-side switch 531, or may be another diode. The semiconductor chips on which the switches and diodes are formed may be different from each other.

A drain terminal 540a is connected to the drain electrode of the high-side switch 521. A source terminal 540b is connected to the source electrode of the low-side switch 531. A midpoint terminal 540c is connected to a midpoint between the high-side switch 521 and the low-side switch 531. A gate terminal 540d is connected to each of the gate electrodes of the high-side switch 521 and the low-side switch 531.

The drain electrode and the source electrode correspond to a first electrode and a second electrode. The drain terminal 540a, the source terminal 540b, and the midpoint terminal 540c are included in the first and second terminals. The gate terminal 540d is included in the control terminals.

All of the semiconductor chips and some of the terminals described so far are covered and protected by a coating resin 520. The tip side of the terminals is exposed from the coating resin 520. The tips of these terminals are connected to the P bus bar 501 to the W-phase bus bar 505 and a control board 580.

A tip of the drain terminal 540a is connected to the P bus bar 501. A tip of the source terminal 540b is connected to the N bus bar 502. In this configuration, the high-side switch 521 and the low-side switch 531 are sequentially connected in series from the P bus bar 501 to the N bus bar 502.

The midpoint terminal 540c of the U-phase semiconductor module 511 is connected to a U-phase stator coil of the motor 400 via the U-phase bus bar 503. The midpoint terminal 540c of the V-phase semiconductor module 512 is connected to the V-phase stator coil via the V-phase bus bar 504. The midpoint terminal 540c of the W-phase semiconductor module 513 is connected to the W-phase stator coil via a W-phase bus bar 505.

The gate terminal 540d of each of the high-side switch 521 and the low-side switch 531 included in each of the U-phase semiconductor module 511 to the W-phase semiconductor module 513 is connected to the control board 580.

This control board 580 includes a gate driver. This control board 580 or another board also includes one of a plurality of ECUs. In the drawings, the control board 580 is denoted as CB.

The ECU generates a control signal. This control signal is input to the gate driver. The gate driver amplifies the control signal and outputs it to the gate terminal 540d. Thereby, the high-side switch 521 and the low-side switch 531 are controlled to open and close.

The ECU generates a pulse signal as the control signal. The ECU adjusts the on-duty ratio and a frequency of this pulse signal. The on-duty ratio and the frequency are determined based on the output of a current sensor and the output of a rotation angle sensor (not shown), the target torque of motor 400, the SOC of battery 200, and the like.

When the motor 400 is powered, each of the high-side switch 521 and the low-side switch 531 provided in the three-phase semiconductor module is PWM-controlled by the output of the control signal from the ECU. Thereby, a three-phase alternating current is generated in the power conversion device 500.

When the motor 400 generates (i.e., regenerates) electricity, the ECU stops the output of the control signal, for example. In this way, the AC power generated by the power generation passes through the diodes provided in the three phase semiconductor module. As a result, the AC power is converted to DC power.

The types of switch elements included in each of the U-phase semiconductor module 511 to the W-phase semiconductor module 513 are not particularly limited. For example, an IGBT may be used as the switch element instead of the MOSFET. Also, the types of switch elements provided in each of the U-phase semiconductor module 511 to the W-phase semiconductor module 513 may be the same or different.

The material for forming the semiconductor chip on which semiconductor elements such as switches and diodes are formed is not particularly limited. As the material for forming the semiconductor chip, for example, a semiconductor such as Si or a wide-gap semiconductor such as SiC can be appropriately employed.

Each of the semiconductor modules may also include a plurality of high-side switches 521 connected in parallel and a plurality of low-side switches 531 connected in parallel. Also in such a configuration, a diode is connected in anti-parallel to each of the plurality of switches.

### <Configuration of Power Conversion Unit>

Next, the configuration of the power conversion unit 300 will be described. Three directions orthogonal to one another are referred to as an x-direction, a y-direction, and a z-direction. The x-direction corresponds to a lateral direction. The y-direction corresponds to a vertical direction. The z-direction corresponds to an aligned direction.

### <Coating Resin>

Each of the U-phase semiconductor module 511 to the W-phase semiconductor module 513 has the coating resin 520 described above. The coating resin 520 is made of epoxy resin, for example. The coating resin 520 is formed by, for example, a transfer molding method. All of the semiconductor chips described so far and part of the various terminals are integrally covered with this coating resin 520. The coating resin 520 corresponds to the resin portion.

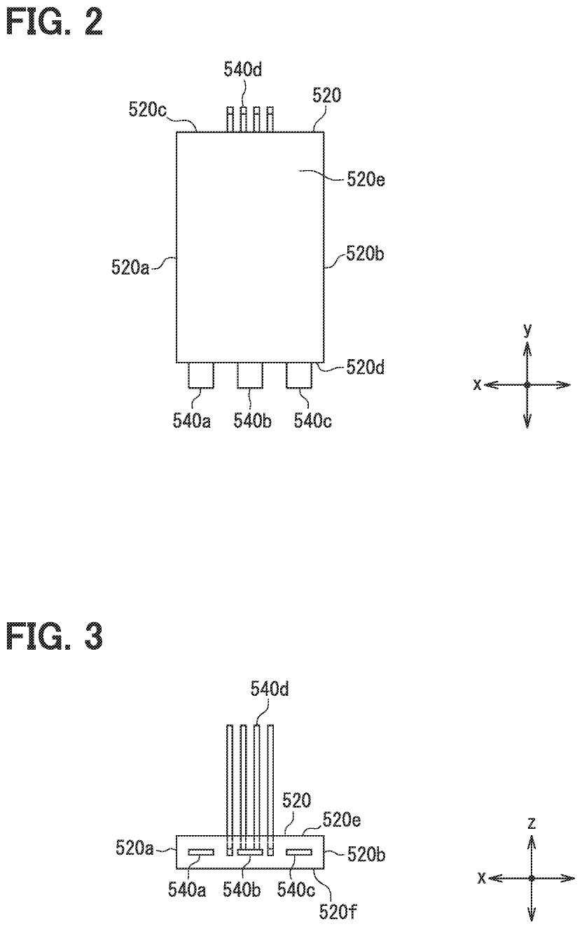

As shown in FIGS. 2 and 3, the coating resin 520 has a flat shape with a thin thickness in the z-direction. The coating resin 520 has a rectangular parallelepiped shape with six faces. The coating resin 520 has a left surface 520a and a right surface 520b spaced apart in the x-direction, an upper surface 520c and a lower surface 520d spaced apart in the y-direction, and a first main surface 520e and a second main surface 520f spaced apart in the z-direction.

As shown in FIG. 2, in the present embodiment, the tips of the drain terminal 540a, the source terminal 540b, and the midpoint terminal 540c are exposed from the lower surface 520d. The tip sides of these three terminals extend in the y-direction away from the lower surface 520d. The drain terminal 540a, the source terminal 540b, and the midpoint terminal 540c are arranged in order from the left surface 520a to the right surface 520b in the x-direction.

Also, the tip of the gate terminal 540d is exposed from the upper surface 520c. The tip side of the gate terminal 540d extends in the y-direction away from the upper surface 520c, then bends and extends in the z-direction toward the first main surface 520e.

Although not shown, a part of the conductive portion connected to the semiconductor chip is covered with the coating resin 520. The rest of the conductive portion is exposed from the first main surface 520e and the second main surface 520f of the coating resin 520, respectively. The conductive portion has a function of conducting heat generated in the semiconductor chip to the outside of the coating resin 520. The conductive portion of the present embodiment also serves to connect the high-side switch 521 and the low-side switch 531 in series.

### <Cooling Device>

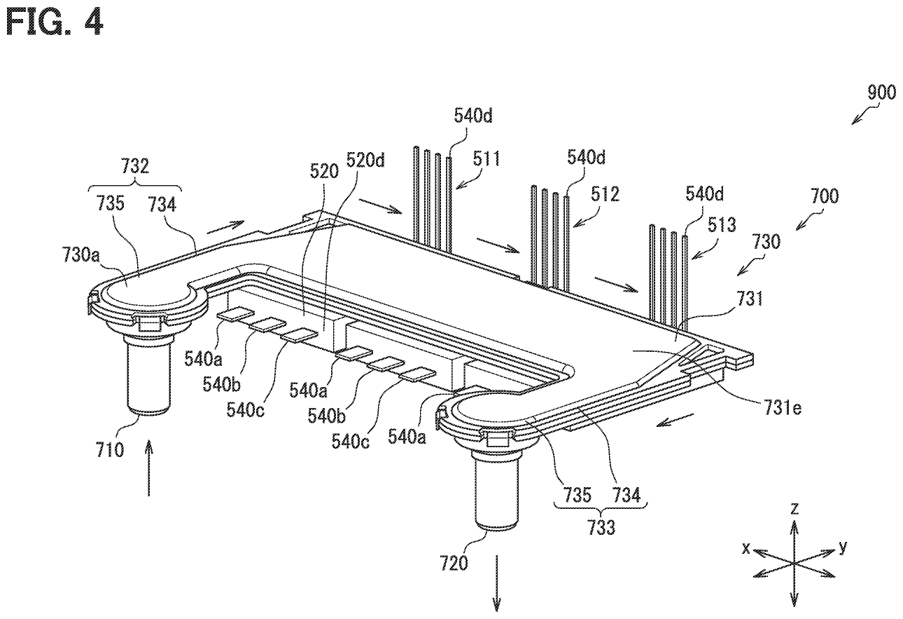

The power conversion unit 300 has a cooling device 700 shown in FIGS. 4 to 7 in addition to the power conversion device 500. The cooling device 700 functions to cool the U-phase semiconductor module 511 to the W-phase semiconductor module 513.

As shown in FIG. 4, the cooling device 700 has a supply pipe 710, a discharge pipe 720, and a cooling unit 730. The supply pipe 710 and the discharge pipe 720 are connected via the cooling unit 730. Refrigerant is supplied to the supply pipe 710. This refrigerant flows from the supply pipe 710 to the discharge pipe 720 through the inside of the cooling unit 730.

The supply pipe 710 and the discharge pipe 720 each extend in the y-direction. The supply pipe 710 and the discharge pipe 720 are spaced apart in the x-direction. The cooling unit 730 has a flat shape with a small thickness in the z-direction.

### <Cooling Portion>

Specifically, the cooling unit 730 has a facing portion 731, a first arm portion 732, and a second arm portion 733. Each of the first arm portion 732 and the second arm portion 733 is connected to the facing portion 731. Each of these three components has a hollow through which refrigerant flows. The hollow of each of these three components communicates.

The supply pipe 710 is connected to the first arm portion 732. The discharge pipe 720 is connected to the second arm portion 733. Due to this configuration, the refrigerant supplied from the supply pipe 710 flows to the facing portion 731 via the first arm portion 732. The refrigerant that has flowed through the facing portion 731 flows to the discharge pipe 720 via the second arm portion 733. The flow direction of this refrigerant is indicated by solid arrows in FIG. 4.

The facing portion 731 includes a first side surface 731a and a second side surface 731b spaced apart in the x-direction, a third side surface 731c and a fourth side surface 731d spaced apart in the y-direction, and an outer surface 731e and an inner surface 731f spaced apart in the z-direction. The first side surface 731a and the second side surface 731b correspond to two side surfaces. The third side surface 731c and the fourth side surface 731d correspond to two end surfaces.

Each of the first arm portion 732 and the second arm portion 733 is connected to the fourth side surface 731d of the facing portion 731. The first arm portion 732 and the second arm portion 733 are separated in the x-direction. The first arm portion 732 is positioned closer to a side of the first side surface 731a than the second arm portion 733 in the x-direction. The second arm portion 733 is located closer to a side of the second side surface 731b than the first arm portion 732.

Each of the first arm portion 732 and the second arm portion 733 extends in the y-direction away from the fourth side surface 731d. Each of the first arm portion 732 and the second arm portion 733 has an upper outer surface 730a and a lower inner surface 730b aligned in the z-direction. The upper outer surface 730a is flush with the outer surface 731e. The lower inner surface 730b on the facing portion 731 side is flush with the inner surface 731f. However, the tip side of the lower inner surface 730b which is spaced apart in the y-direction from the facing portion 731 protrudes slightly in the direction away from the upper outer surface 730a in the z-direction rather than the inner surface 731f.

The supply pipe 710 is connected to a portion of the lower inner surface 730b of the first arm portion 732 that slightly protrudes from the inner surface 731f. The discharge pipe 720 is connected to a portion of the lower inner surface 730b of the second arm portion 733 that slightly protrudes from the inner surface 731f. In other words, the supply pipe 710 is connected to the lower inner surface 730b on the tip side of the first arm portion 732. The discharge pipe 720 is connected to the lower inner surface 730b on the tip side of the second arm portion 733.

The extension directions of each of the first arm portion 732 and the second arm portion 733 and the extension directions of each of the supply pipe 710 and the discharge pipe 720 are in an intersecting relationship. Therefore, the flow direction of the refrigerant flowing in the supply pipe 710 is changed at a connection point between the supply pipe 710 and the first arm portion 732. The flow direction of the refrigerant flowing in the second arm portion 733 is changed at a connection point between the second arm portion 733 and the discharge pipe 720.

In the following description, the facing portion 731 side of each of the first arm portion 732 and the second arm portion 733 is referred to as an extension portion 734 for the sake of simplicity. The tip side of each of the first arm portion 732 and the second arm portion 733 is referred to as a pipe connecting portion 735. The pipe connecting portion 735 changes the flow direction of the refrigerant.

<Position of Supply Pipe and Discharge Pipe in x-Direction>

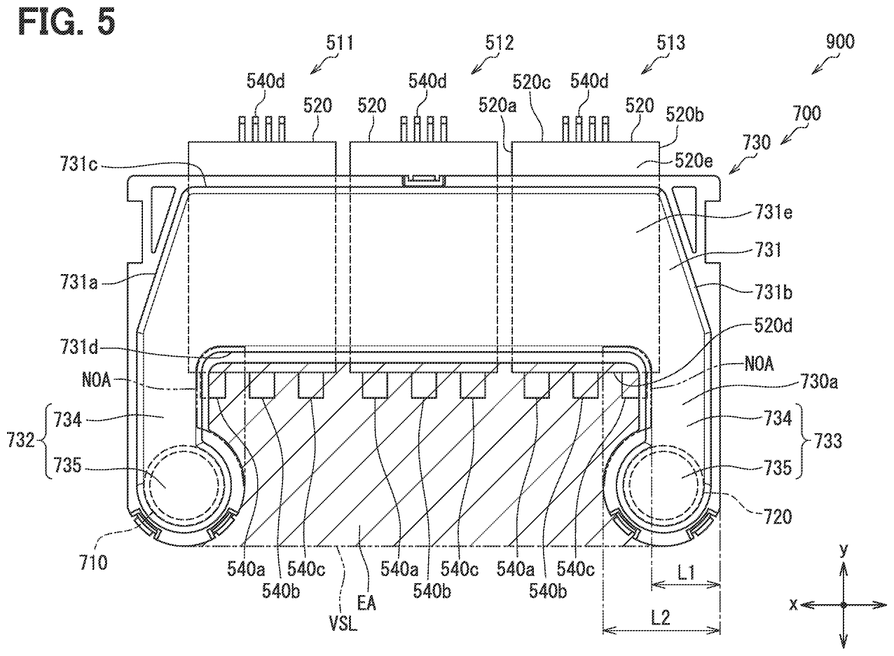

For example, as shown in FIG. 5, the extension portion 734 has a constant length L1 in the x-direction. On the other hand, the length in the x-direction of the pipe connecting portion 735 is indefinite. A portion of the pipe connecting portion 735 to which the supply pipe 710 and the discharge pipe 720 are connected has a circular shape on a plane orthogonal to the z-direction. In FIG. 5, the supply pipe 710 and the discharge pipe 720 are indicated by dashed lines.

An outer diameter of each of the supply pipe 710 and the discharge pipe 720 is longer than a length of the extension portion 734 in the x-direction. Therefore, a longest length L2 in the x-direction of the pipe connecting portion 735 is longer than a longest length L1 in the x-direction of the extension portion 734.

Due to the above mentioned length relationship in the x-direction and the respective shapes of the extension portion 734 and the pipe connecting portion 735, the extension portion 734 as a whole is located in a part of the projection area of the pipe connecting portion 735 in the y-direction. In the present embodiment, the fourth side surface 731d is positioned in the non-overlapping area NOA that does not overlap the extension portion 734 in the projection area of the pipe connecting portion 735 in the y-direction. In FIG. 5, the area between the pipe connecting portion 735 and the fourth side surface 731d in the non-overlapping area NOA is shown enclosed by a chain double-dashed line.

As a matter of course, the fourth side surface 731d positioned in the non-overlapping area NOA of the pipe connecting portion 735 is located between the first side surface 731a and the second side surface 731b in the x-direction. The extension portion 734 connected to the pipe connecting portion 735 extends in the y-direction from the fourth side surface 731d.

Due to such a configuration, the position in the x-direction of the pipe connecting portion 735 of each of the first arm portion 732 and the second arm portion 733 is between the first side surface 731a and the second side surface 731b. All positions in the x-direction of each of the first arm portion 732 and the second arm portion 733 are between the first side surface 731a and the second side surface 731b. All positions in the x-direction of each of the supply pipe 710 connected to the first arm portion 732 and the discharge pipe 720 connected to the second arm portion 733 are between the first side surface 731a and the second side surface 731b.

In the present embodiment, a length in the x-direction of a portion defining the hollow through which the refrigerant flows on the third side surface 731c is shorter than a length in the x-direction of a portion defining the hollow through which the refrigerant flows on the fourth side surface 731d. As a result, the refrigerant flows smoothly from the first arm portion 732 to the facing portion 731 and the refrigerant flows also smoothly from the facing portion 731 to the second arm portion 733.

Due to the difference in length, as shown in FIG. 5, each of the first side surface 731a and the second side surface 731b extends in a direction inclined with respect to the y-direction on a plane perpendicular to the z-direction. Each of the first side surface 731a and the second side surface 731b extends obliquely in such a manner that a distance between the first side surface 731a and the second side surface 731b gradually extends in the y-direction from the third side surface 731c toward the fourth side surface 731d.

Therefore, strictly speaking, all of the positions in the x-direction of the first arm portion 732 and the second arm portion 733 are between the fourth side surface 731d side of the first side surface 731a and the fourth side surface 731d side of the second side surface 731b. All of the portions in the x-direction of the supply pipe 710 connected to the first arm portion 732 and the discharge pipe 720 connected to the second arm portion 733 are between the fourth side surface 731d side of the first side surface 731a and the fourth side surface 731d side of the second side surface 731b.

### <Surrounding Area>

Due to the configuration described above, as shown in FIG. 5, a planar shape of the cooling unit 730 facing the z-direction is a C-shape. A surrounding area EA is defined by the facing portion 731, the first arm portion 732, and the second arm portion 733 of the cooling unit 730.

The surrounding area EA is defined in the y-direction by the fourth side surface 731d and a virtual straight line VSL connecting the tip of the first arm portion 732 and the tip of the second arm portion 733. The surrounding area EA is defined in the x-direction by the inner surface of the first arm portion 732 on the second arm portion 733 side and the inner surface of the second arm portion 733 on the first arm portion 732 side. In FIG. 5, the surrounding area EA is indicated by diagonal hatching. The virtual straight line VSL is indicated by a two-dot chain line.

### <Power Module>

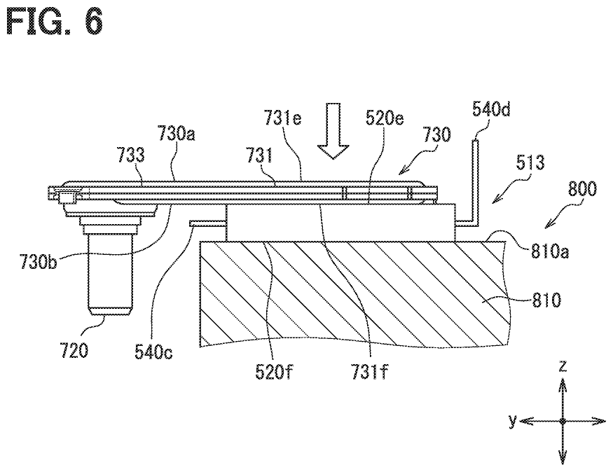

The cooling device 700 is housed together with the power conversion device 500 in a housing 800 made of, for example, aluminum die casting. As shown in FIG. 6, the facing portion 731 of the cooling unit 730 is arranged to face a wall portion 810 of the housing 800 while being spaced apart in the z-direction.

A gap is formed (divided) between the inner surface 731f of the facing portion 731 and the mounting surface 810a of the wall portion 810. The U-phase semiconductor module 511, a V-phase semiconductor module 512, and a W-phase semiconductor module 513 are provided in this gap. The power module 900 includes a plurality of these semiconductor modules and the cooling device 700.

The U-phase semiconductor module 511, the V-phase semiconductor module 512, and the W-phase semiconductor module 513 are arranged in order from the first side surface 731a toward the second side surface 731b in the x-direction. The coating resin 520 of these multiple semiconductor modules is provided in the gap between the facing portion 731 and the wall portion 810.

The facing portion 731 of the cooling unit 730 is applied with a biasing force indicated by an outline arrow in FIG. 6. A plurality of semiconductor modules are sandwiched between the facing portion 731 and the wall portion 810 by this biasing force.

Although not shown, a heat transfer member such as grease is provided between the inner surface 731f of the facing portion 731 and the first main surface 520e of the coating resin 520 of the semiconductor module. Similarly, the heat transfer member such as grease is provided between the second main surface 520f of the coating resin 520 and the mounting surface 810a. Due to such a configuration, in the semiconductor module, the cooling device 700 and the wall portion 810 can positively conduct heat. However, the above heat transfer member may be omitted.

The wall portion 810 on which the semiconductor module is provided may not be part of the housing 800. The semiconductor module may be provided on a wall portion 810 that is separate from the housing 800. A circulation path through which the refrigerant flows may be formed inside the wall portion 810.

As shown in FIGS. 5 and 6, the upper surface 520c side and the lower surface 520d side of the coating resin 520 are provided outside the gap. According to this configuration, the tip side of the gate terminal 540d exposed from the upper surface 520c is provided outside the gap. The tip side of each of the drain terminal 540a, the source terminal 540b, and the midpoint terminal 540c exposed from the lower surface 520d is provided outside the gap.

As shown in FIG. 6, the gate terminal 540d extends in the y-direction away from the upper surface 520c, then bends and extends in the z-direction away from the wall portion 810. The gate terminal 540d faces the third side surface 731c of the facing portion 731 in the y-direction.

Each of the drain terminal 540a, the source terminal 540b, and the midpoint terminal 540c extends in the y-direction away from the lower surface 520d. The positions of the tips of the plurality of terminals protruding from the lower surface 520d in the z-direction are located between the inner surface 731f of the facing portion 731 and the mounting surface 810a of the wall portion 810. The tips of these terminals are aligned with the above-described surrounding area EA in the z-direction.

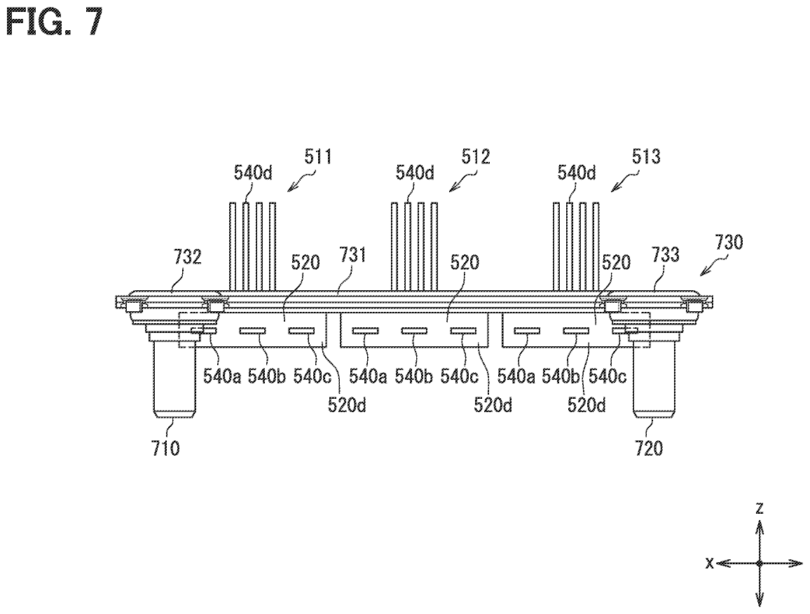

Further, as shown in FIG. 5, the tips of the plurality of terminals protruding from the lower surface 520d are opposed to the supply pipe 710 and the discharge pipe 720 in the direction along the plane perpendicular to the z-direction. In particular, in an overlapped region indicated by the dashed line in FIG. 7, the lower surface 520d of the coating resin 520 of the U-phase semiconductor module 511 located on the end side and the drain terminal 540a protruding from this lower surface 520d face the supply pipe 710 in the y-direction. The lower surface 520d of the coating resin 520 of the W-phase semiconductor module 513 and the midpoint terminal 540c protruding from the lower surface 520d are opposed to the discharge pipe 720 in the y-direction.

As described above, the phase bus bar is connected to the midpoint terminal 540c. Although not shown, this phase bus bar is also aligned with the surrounding area EA in the z-direction. A configuration in which a part of the phase bus bar is provided in the surrounding area EA can also be adopted.

Also, the P bus bar 501 is connected to the drain terminal 540a. The N bus bar 502 is connected to the source terminal 540b. These P bus bar 501 and N bus bar 502 may be arranged side by side with the surrounding area EA in the z-direction, or part of them may be provided in the surrounding area EA.

### <Operation and Effects>

As described above, each of the supply pipe 710 connected to the first arm portion 732 and the discharge pipe 720 connected to the second arm portion 733 faces the lower surface 520d of the coating resin 520 provided in the semiconductor module in the y-direction. It is possible to suppress an increase in the size of the cooling device 700 in the x-direction. An increase in the size of the power module 900 in the x-direction is suppressed.

In particular, in the present embodiment, the positions in the x-direction of each of the first arm portion 732, the supply pipe 710, the second arm portion 733, and the discharge pipe 720 are all located between the first side surface 731a and the second side surface 731b of the facing portion 731. Therefore, the increase in the size of the cooling device 700 in the x-direction is suppressed.

In addition, specifically for the cooling unit 730, all the positions in the x direction of the first arm portion 732 and the second arm portion 733 are located between the first side surface 731a and the second side surface 731b. Therefore, the increase in the size of the cooling unit 730 in the x-direction is suppressed.

As described above, the tips of a plurality of terminals protruding from the lower surface 520d of the coating resin 520 of the semiconductor module face the supply pipe 710 and the discharge pipe 720 in the direction along the plane perpendicular to the z-direction. In particular, the drain terminal 540a of the U-phase semiconductor module 511 faces the supply pipe 710 in the y-direction. The midpoint terminal 540c of the W-phase semiconductor module 513 faces the discharge pipe 720 in the y-direction.

According to the above-mentioned configuration, the thermal resistance between the terminals of the semiconductor module and the cooling device 700 is decreased. This configuration enables to suppress temperature rise of the terminals.

The surrounding area EA defined by the facing portion 731, the first arm portion 732, and the second arm portion 733 of the cooling unit 730 and the tips of the plurality of terminals protruding from the lower surface 520d of the coating resin 520 are arranged side by side in the z-direction.

As a result, the temperature of the air located in the surrounding area EA is easily lowered by the refrigerant flowing through the hollows of the three constituent elements of the cooling unit 730. The temperature of the tips of the plurality of terminals protruding from the lower surface 520d is easily lowered by this air.

### Second Embodiment

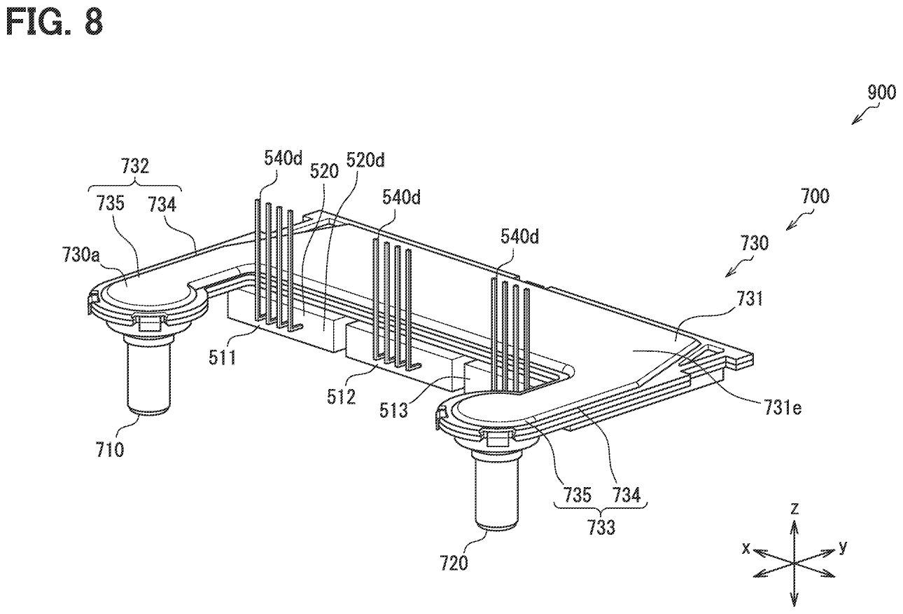

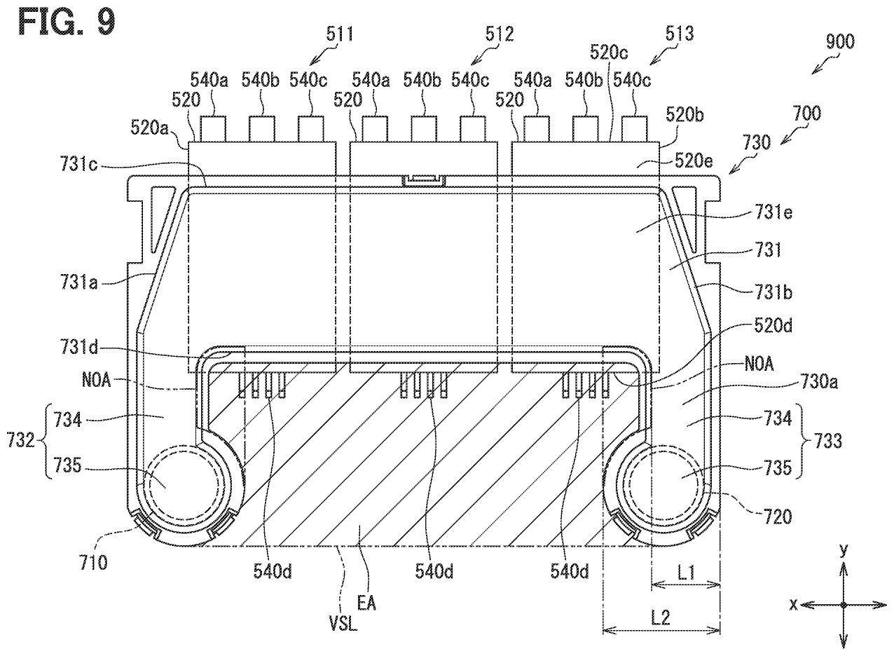

Next, a second embodiment will be described with reference to FIGS. 8 and 9.

In the first embodiment, the tips of the gate terminals 540d are exposed from the upper surface 520c of the coating resin 520, and the tips of each of the drain terminal 540a, the source terminal 540b, and the midpoint terminal 540c are exposed from the lower surface 520d.

On the other hand, in the present embodiment, the tips of each of the drain terminal 540a, the source terminal 540b, and the midpoint terminal 540c are exposed from the upper surface 520c of the coating resin 520, and the tips of the gate terminals 540d are exposed from the lower surface 520d.

Part of the portion of the gate terminals 540d extending in the z-direction is located in the surrounding area EA. According to this configuration, the gate terminal 540d tends to actively exchange heat with the air in the surrounding area EA.

The power module 900 described in the present embodiment includes components equivalent to those of the power module 900 described in the first embodiment. Therefore, the power module 900 of the present embodiment has the same effects as the power module 900 described in the first embodiment. Therefore, the description regarding the effects is omitted.

### First Modification

A combination of terminals exposed from the upper surface 520c and the lower surface 520d is not limited to the configurations shown in the first and second embodiments. The drain terminal 540a, the source terminal 540b, the midpoint terminal 540c, and the gate terminal 540d may be exposed from either the upper surface 520c, or the lower surface 520d.

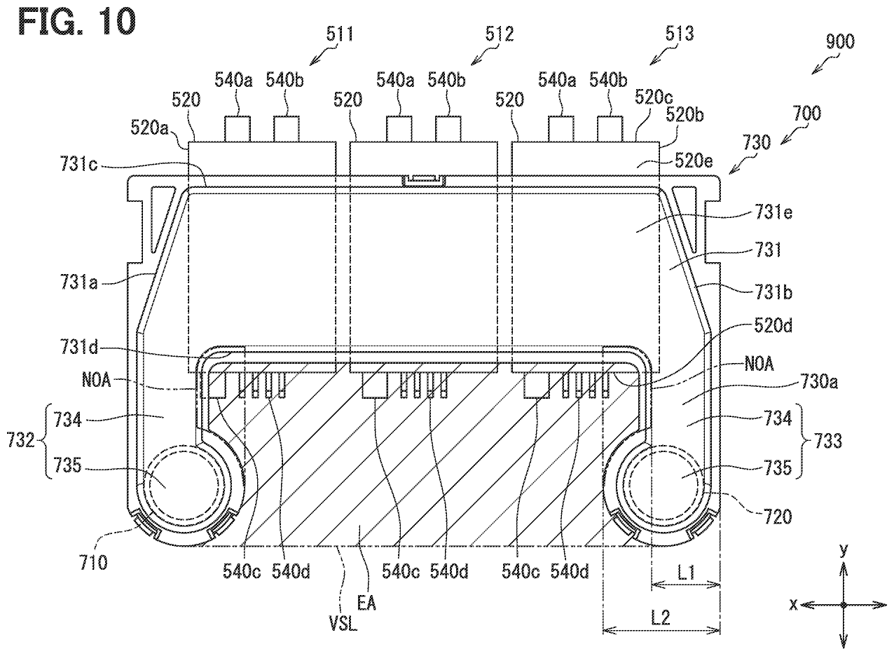

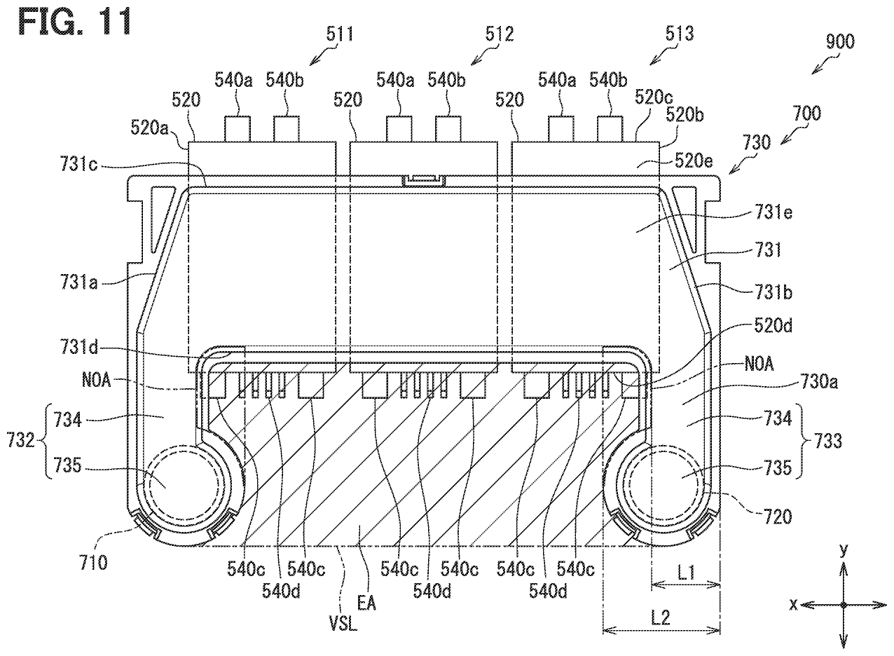

For example, as shown in FIGS. 10 and 11, a configuration in which the drain terminal 540a and the source terminal 540b are exposed from the upper surface 520c can also be adopted. In a modification shown in FIG. 10, the midpoint terminal 540c and the gate terminal 540d are exposed from the lower surface 520d. In a modification shown in FIG. 11, two midpoint terminals 540c having the same potential and the gate terminal 540d are exposed from the lower surface 520d.

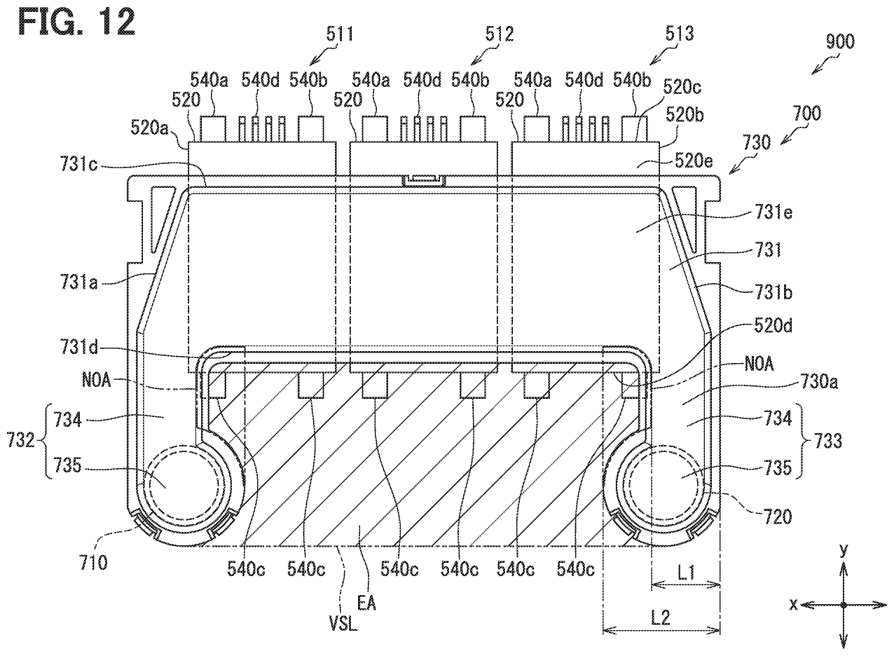

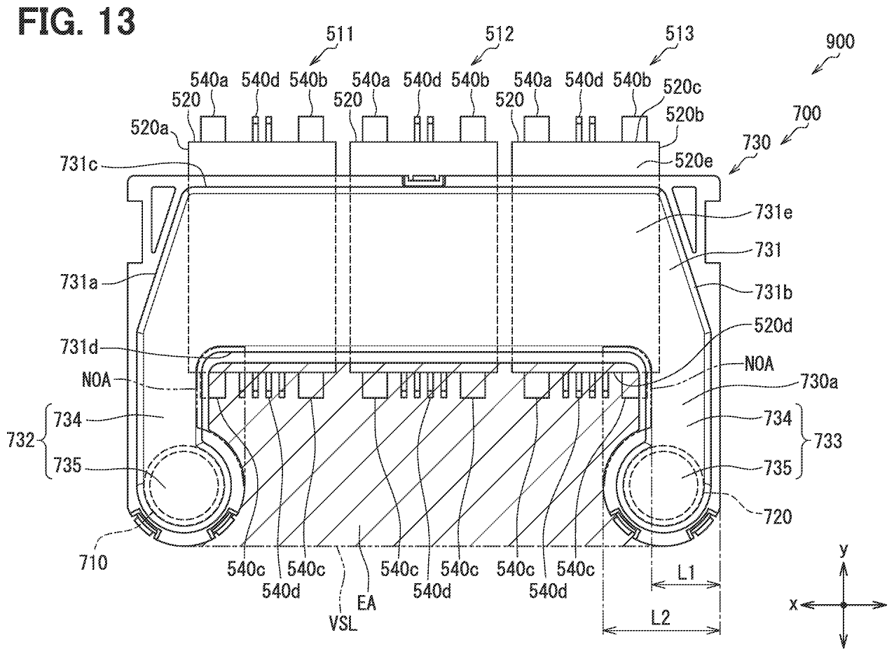

For example, as shown in FIGS. 12 and 13, a configuration in which the drain terminal 540a, the source terminal 540b, and the gate terminal 540d are exposed from the upper surface 520c can also be adopted. As shown in FIGS. 12 and 13, the number of gate terminals 540d exposed from the upper surface 520c is not particularly limited.

In a modification shown in FIG. 12, two midpoint terminals 540c having the same potential are exposed from the lower surface 520d. In a modification shown in FIG. 13, two midpoint terminals 540c having the same potential and a gate terminal 540d are exposed from the lower surface 520d. The number of gate terminals 540d exposed from the upper surface 520c and the number of gate terminals 540d exposed from the lower surface 520d may be different or the same.

### Second Modification

In each embodiment, an example in which the semiconductor module is provided in the gap defined between the facing portion 731 of the cooling device 700 and the wall portion 810 of the housing 800 is shown. Alternatively, for example, a configuration in which two cooling devices 700 are prepared and a semiconductor module is provided in the gap between the two facing portions 731 of two cooling devices 700 can also be adopted.

### Third Modification

In each embodiment, an example in which the plurality of semiconductor modules are provided in the gap defined between the facing portion 731 of the cooling device 700 and the wall portion 810 of the housing 800 is shown.

Alternatively, a configuration in which one semiconductor module is provided in this gap can also be adopted. A configuration in which this one semiconductor module faces at least one of the supply pipe 710 and the discharge pipe 720 in the y-direction can also be adopted.

### OTHER MODIFICATIONS

In this embodiment, an example in which the power conversion device 500 includes an inverter is shown. Alternatively, the power conversion device 500 may include a converter in addition to the inverter.

In this embodiment, an example in which the power conversion unit 300 is included in the in-vehicle system 100 for an electric vehicle is shown. Alternatively, application of the power conversion unit 300 may not be particularly limited to the above example. For example, a configuration in which power conversion unit 300 is included in a system of a hybrid vehicle having a motor and an internal combustion engine may also be adopted.

In this embodiment, an example in which one motor 400 is connected to the power conversion unit 300 is shown. Alternatively, a configuration in which a plurality of motors 400 are connected to power conversion unit 300 may also be adopted. In this case, the power conversion unit 300 has a plurality of three-phase semiconductor modules for configuring an inverter.

While the present disclosure has been described with reference to embodiments thereof, it is to be understood that the disclosure is not limited to the embodiments and constructions. The present disclosure encompasses various modified examples and modifications within an equivalent scope. In addition, although various combinations and modes are shown in the present disclosure, other combinations and modes including only one element, more elements, or less elements are also within the scope and idea of the present disclosure.

What is claimed is:

1. A power module, comprising:
a semiconductor module having a semiconductor element, a terminal connected to the semiconductor element, and a resin portion covering each of the semiconductor element and the terminal; and
a cooling device having a cooling unit provided in the semiconductor module so as to be capable of conducting heat, a supply pipe configured to supply refrigerant to an interior of the cooling unit, and a discharge pipe configured to discharge the refrigerant that is flowed inside the cooling unit, wherein
the supply pipe and the discharge pipe are spaced apart in a lateral direction orthogonal to an alignment direction in which the semiconductor module and the cooling unit are aligned,
the supply pipe and the discharge pipe face the semiconductor module in a vertical direction orthogonal to the lateral direction and the alignment direction,
the terminal has a first terminal connected to a first electrode of the semiconductor element, a second terminal connected to a second electrode of the semiconductor element, and a control terminal configured to control energization between the first electrode and the second electrode of the semiconductor element, and
in a surrounding area surrounded by a portion of the cooling unit where the semiconductor module is provided and a portion of the cooling unit connected to the supply pipe and the discharge pipe, a part of the portion of the first terminal exposed from the resin portion or a part of the portion of the second terminal exposed from the resin portion is located.

2. The power module according to claim 1, wherein
the cooling unit forms a C-shape when viewed from the alignment direction, and the supply pipe and the discharge pipe are provided at both ends of the C-shaped cooling unit.

3. The power module according to claim 1, wherein
the cooling unit has a facing portion aligned with the resin portion in the alignment direction, a first arm portion extending in the vertical direction from the facing portion, and a second arm portion spaced apart from the first arm portion in the lateral direction and extending in the vertical direction from the facing portion, and
the surrounding area is an area surrounded by the first arm portion, the second arm portion, and the facing portion.

4. The power module according to claim 1, wherein
a plurality of the semiconductor modules are arranged in the lateral direction, and
at least one of the plurality of semiconductor modules faces one of the supply pipe and the discharge pipe in the vertical direction.

5. The power module according to claim 3, wherein
a position in the lateral direction of each of the supply pipe and the discharge pipe is located between two side surfaces aligned in the lateral direction in the facing portion.

6. A power module, comprising:
a semiconductor module having a semiconductor element, a terminal connected to the semiconductor element, and a resin portion covering each of the semiconductor element and the terminal; and
a cooling device having a cooling unit provided in the semiconductor module so as to be capable of conducting heat, a supply pipe configured to supply refrigerant to an interior of the cooling unit, and a discharge pipe configured to discharge the refrigerant that is flowed inside the cooling unit, wherein
the supply pipe and the discharge pipe are spaced apart in a lateral direction orthogonal to an alignment direction in which the semiconductor module and the cooling unit are aligned,
the supply pipe and the discharge pipe face the semiconductor module in a vertical direction orthogonal to the lateral direction and the alignment direction,
the semiconductor element has an active element,
the terminal has a first terminal connected to a first electrode of the active element, a second terminal connected to a second electrode of the active element, and a control terminal configured to control energization between the first electrode and the second electrode of the active element, and
one of the first terminal and the second terminal faces one of the supply pipe and the discharge pipe in the vertical direction.

7. A power module, comprising:
a semiconductor module having a semiconductor element, a terminal connected to the semiconductor element, and a resin portion covering each of the semiconductor element and the terminal; and
a cooling device having a cooling unit provided in the semiconductor module so as to be capable of conducting heat, a supply pipe configured to supply refrigerant to an interior of the cooling unit, and a discharge pipe configured to discharge the refrigerant that is flowed inside the cooling unit, wherein
the supply pipe and the discharge pipe are spaced apart in a lateral direction orthogonal to an alignment direction in which the semiconductor module and the cooling unit are aligned,
the supply pipe and the discharge pipe face the semiconductor module in a vertical direction orthogonal to the lateral direction and the alignment direction,
the cooling unit has a facing portion aligned with the resin portion in the alignment direction, a first arm portion extending in the vertical direction from the facing portion, and a second arm portion spaced apart from the first arm portion in the lateral direction and extending in the vertical direction from the facing portion, the supply pipe extends in the alignment direction and is connected to the first arm portion, and
the discharge pipe extends in the alignment direction and is connected to the second arm portion.

8. The power module according to claim 7, wherein
a plurality of the semiconductor modules are arranged in the lateral direction, and
at least one of the plurality of semiconductor modules faces one of the supply pipe and the discharge pipe in the vertical direction.

9. The power module according to claim 7, wherein
a position in the lateral direction of each of the supply pipe and the discharge pipe is located between two side surfaces aligned in the lateral direction in the facing portion.

10. The power module according to claim 7, wherein
each of the first arm portion and the second arm portion extends from one of two end surfaces arranged in the vertical direction in the facing portion, and
a surrounding area surrounded by the first arm portion, the second arm portion, and one of the two end surfaces, and a portion of the terminal exposed from the resin portion are arranged in the alignment direction.

11. The power module according to claim 10, wherein
a part of a portion of the terminal exposed from the resin portion is located in the surrounding area.

12. The power module according to claim 7, wherein
the semiconductor element has an active element,
the terminal has a first terminal connected to a first electrode of the active element, a second terminal connected to a second electrode of the active element, and a control terminal configured to control energization between the first electrode and the second electrode of the active element.

13. The power module according to claim 12, wherein
one of the first terminal and the second terminal faces one of the supply pipe and the discharge pipe in the vertical direction.

14. A power module, comprising:
a plurality of semiconductor modules having a semiconductor element, a terminal connected to the semiconductor element, and a resin portion covering each of the semiconductor element and the terminal; and
a cooling device having a cooling unit provided in the plurality of semiconductor modules so as to be capable of conducting heat, a supply pipe configured to supply refrigerant to an interior of the cooling unit, and a discharge pipe configured to discharge the refrigerant that is flowed inside the cooling unit, wherein
the supply pipe and the discharge pipe are spaced apart in a lateral direction orthogonal to an alignment direction in which the semiconductor module and the cooling unit are aligned,
the supply pipe and the discharge pipe face the plurality of semiconductor module in a vertical direction orthogonal to the alignment direction and the lateral direction,
the cooling unit has a facing portion configured to face the plurality of semiconductor modules and extend in the lateral direction, a first arm portion configured to extend in the vertical direction from the facing portion and be connected to the supply pipe, and a second arm portion configured to be spaced apart from the first arm portion in the lateral direction, extend in the vertical direction from the facing portion, and be connected to the discharge pipe,
the plurality of the semiconductor modules are arranged in the lateral direction, and
a part of the supply pipe and a part of the discharge pipe are located in a surrounding area surrounded by the first arm portion, the second arm portion, and the facing portion.

15. The power module according to claim 14, wherein
a position in the lateral direction of each of the supply pipe and the discharge pipe is located between two side surfaces aligned in the lateral direction in the facing portion.

16. The power module according to claim 14, wherein
the semiconductor element has an active element, and
the terminal has a first terminal connected to a first electrode of the active element, a second terminal connected to a second electrode of the active element, and a control terminal configured to control energization between the first electrode and the second electrode of the active element.

17. The power module according to claim 16, wherein
one of the first terminal and the second terminal faces one of the supply pipe and the discharge pipe in a vertical direction perpendicular to each of the alignment direction and the lateral direction.
